(19) United States
(12) Patent Application Publication
(10) Pub. No.: US 2004/0225388 A1
(43) Pub. Date: Nov. 11, 2004

(54) Fully digitized audio system

(76) Inventors: Guohua Zhang, Guangzhou (CN); Limin Lai, Guangzhou (CN); Enyi Zhan, Guangzhou (CN); Aihua Zhou, Guangzhou (CN)

Correspondence Address: MAYER, FORTKORT & WILLIAMS, PC, 251 NORTH AVENUE WEST, 2ND FLOOR, WESTFIELD, NJ, 07090, US

(21) Appl. No.: 10/197,057

(22) Filed: Jul. 17, 2002

(30) Foreign Application Priority Data
Jul. 17, 2001 (CN) 01127632.0

(51) Int. Cl. G06F 17/00; H03G 3/00

(52) U.S. Cl. 700/94; 381/104; 381/106

(57) ABSTRACT

The invention relates to a fully digitized audio system comprising a power supply and a decode and sound field effect process unit, characterized in that a digital audio signal output from the decode and sound field effect process unit is transmitted to a control and encode unit where audio and control signals are encoded, and coupled to a digital sound box through a digital transmission terminal in the control and encode unit. The invention adopts totally digitized audio signal processing according to the concept of mechatronics, solving the problem of distortions rising throughout the procedure from input, process, distribution, transmission and amplification to sounding, to ensure a controllable hi-fi output of audio signal. The audio system according to the present invention provides high fidelity, good controllability, and easiness of assembling, and is suitable for mass production of advance audio systems.

### FIELD OF THE INVENTION

The present invention relates to an audio system, more particularly to a fully digitized audio system designed on the basis of mechatronics.

### RELATED ART

Audio systems are everywhere nowadays. The acoustics requirements on audio systems, especially on domestic systems, are increasingly so strict that super hi-fis have already been put into consideration. The conventional audio systems are designed on the basis of analog signal propagation and process, with the exception of some partial circuits such as digital audio signal sources and decoding circuits for respective digital signal sources. The existing digital circuits in conventional systems, though, are partial or substitutionary modules of analog nature. The limitations of analog circuits result in distortions in audio signals occurring at various links throughout the chain from input via process, transmission, amplification and etc. to loud-speaking, and difficulties in design and manufacture as well. Since especially the amplification circuits and loudspeakers of conventional audio systems are not designed as integrated systems (not designed according to mechatronics), there are, of course, many problems encountered which are difficult to overcome systematically, and mainly consist of the following:

1. difficulties in load matching between an amplifier and a loudspeaker/loudspeakers;

2. linear and non-linear distortions resulting from analog amplification (including voltage pre-amplification and power output amplification);

3. distortions and power losses resulting from passive power frequency dividers (an increase in the output internal impedance towards loudspeaker units and decrease in compliance);

4. complexities and difficulties in manufacturing and adjusting a sound box;

5. difficulties in handling phase-frequency distortion or transient distortion due to high complications of the phase-frequency characteristics of an entire system ranging from amplifiers to loudspeakers;

6. inefficiency in power amplification resulting in a very expensive manufacturing cost for power amplification units in hi-fi systems; and

7. many more difficulties in the design and manufacture of AV hi-fi systems with uncertainties as to consistency among products.

### SUMMERY OF THE INVENTION

It is an object of the present invention to provide a fully digitized audio system adopting digital transmission and digital processes for the whole procedure, in which the sound box, due to an integrated mechatronic structure, offers high fidelity, higher controllability, easy assembling, convenience in manufacture and adjustment, as well as a higher performance/price ratio.

The above object of the invention can be achieved by a fully digitized audio system including a decode and sound field acoustics effect process unit as well as a power supply, characterized in that digital audio signals output from a decode and sound field acoustics effect process unit is fed to a control and encode unit, where the audio signal and control signal are encoded and coupled with a digital sound box unit via a digital transmission terminal in the control and encode unit.

The object of the invention can be further achieved through following features: the control and encode unit includes a digital audio signal channel divider, a volume and function controller, a digital audio and control encoder and a digital transmission terminal, wherein, upon the digital audio signal from the decode and sound field acoustics effect process unit is processed by the digital audio signal channel divider, the control signal from the volume and function controller and other corresponding control signals are encoded into a digital audio signal through the digital audio and control encoder, such that a standard encoded audio digital signal stream containing control information is formed and is output from the digital transmission terminal. In addition, the volume and function controller is able to control a gate circuit and an acoustics effect processor. A digital sound box unit includes a digital box terminal, a digital sound box signal processor, a power amplifier, a loudspeaker unit and sound boxes. The standard encoded audio digital signal stream from the digital transmission terminal is, after being fed into the digital sound terminal, subjected to digital frequency division, digital phase-frequency correction, digital amplitude-frequency correction, digital volume control and digital peak value correction through the digital box signal processor and, then, divided into two or more channels of digital audio signals with different responsive frequency band to be fed to amplifiers and, finally, to drive the loudspeaker unit. The digital sound box unit also feeds the condition signal related to the digital sound box back to the control and encode unit through the digital sound box terminal and the digital transmission terminal. The digital sound box signal processor, the speaker unit and the box are in a mechatronics structure. The decode and sound field acoustics effect process unit includes a digital audio source, a digital audio source input connector, an analog/audio source, an analog audio source input connector, an analog-to-digital (A/D) converter, a gate circuit, an acoustics effect processor. The acoustics effect processor can output two or more channels of digital audio signals to the control and encode unit. Further, parameters such as cut-off frequency, amplitude-frequency correction, phase-frequency correction and peak value correction of the digital sound box signal processor in the digital sound box unit can be adjusted by a sound box parameter adjustment unit.

The control and encode unit of the present system receives digital audio signal input and/or digitized analog audio signal from a standard connector, signals passed over from a control interface and sound box condition signals fed back via the digital transmission terminal. Various signals are processed and encoded digitally in the volume and function control unit and the control and encode unit. The encoded data stream is output through the digital transmission terminal. The standard encoded audio digital signal stream output from the control and encode unit is fed to the digital sound box, and feedback signals from the digital sound box are sent back to the control and encode unit via the digital transmission terminal, transmission media and the digital sound box terminal. The sound box and the digital sound box unit adopt digital and mechatronic conception, wherein the standard encoded digital audio signal stream fed from control and encode unit, through the digital transmission terminal, is subjected to steps of separating the audio signal from the control signal, digital frequency division, digital phase-frequency correction, digital amplitude-frequency correction, digital volume control and digital peak value correction through the digital box signal processor, especially predictive digital phase-frequency correction, digital amplitude-frequency correction as well as setting of control parameters thereof, so as to ensure high fidelity and high stability for the audio output from the digital sound box unit. The digital sound box unit also feeds various related signals back to the control and encode unit through the digital sound box unit terminal and transmission media.

The present invention has following advantages over prior art:

1. distortions caused by conventional analog transmission and analog circuits are reduced, based on the procedure of digital signal transmission and process adopted by the integrated system.

2. a dramatically increase in electric damping of power amplification to loudspeaker due to the adoption of digital frequency division.

3. guaranteed high fidelity and high resolution provided by accurately adjusted amplitude-frequency and the phase-frequency characteristics by means of predictive and adaptive compensation through the whole procedure (mainly for the amplitude-frequency distortion and phase-frequency distortion resulted from the speaker unit, the sounding plane of each speaker unit, sound box, digital divider, amplifier, and etc.)

4. the sound box integration (including the circuit, the loudspeakers and the box) based on mechatronics design, is easy to be adjusted and results in higher performance and simplification in design.

5. standardized interfaces enable any manufacturer to produce sound boxes of highest fidelity according to the present system.

6. suitable for mass production, in particular, of AV5.1 (or above) channel hi-fi systems due to the design principles of the present system which makes the production cost reduced, and the process simplified.

7. easy arrangement of the whole set of the system, resulting in reduced update expenditures.

8. acoustics or tone quality accomomdatable according to individual favorites due to the hi-fi platform structure design of the present system and advanced digital signal process.

9. diversified sound field scene effects.

### BRIEF DESCRIPTION OF THE DRAWINGS

FIG. 1 is a block diagram showing the circuit principle of the present invention;

FIGS. 2(A) to 2(D) are block diagrams showing four possible forms of the control and encode unit;

FIGS. 3(A) to 3(D) are block diagrams showing four possible manners of connection between control and encode unit and the power supply;

FIGS. 4(A) to 4(C) are block diagrams showing three possible manners of connection between control & encode unit and digital speaker; and

FIGS. 5(A) and 5(B) are block diagrams showing two possible manners of the digital sound box unit.

### DETAILED DESCRIPTION OF PREFERRED EMBODIMENT

Now the present invention will be described in detail by means of preferred embodiments in conjunction with the accompanying drawings.

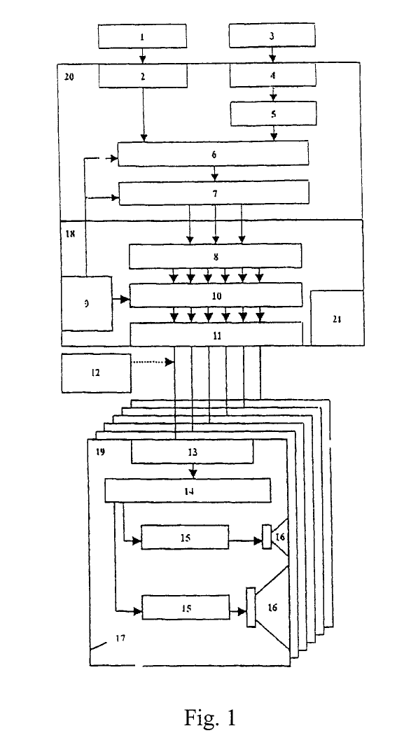

As shown in FIG. 1, a system according to the present invention comprises a decode and sound field acoustics effect process unit 20, a power supply 21, a control and encode unit 18, a digital sound box unit 19 and a sound box 17. The decode and sound field acoustics effect process unit 20 comprises a digital audio source 1, a digital audio source input interface 2, an analog audio source 3, an analog audio source input interface 4, an A/D converter 5, a gate circuit 6 and an acoustic effect processor 7. The control and encode unit 18 comprises a digital audio signal channel divider 8, a volume and function controller 9, a digital audio code and control code encoder 10 and a digital transmission terminal 11. The digital sound box unit 19 comprises a digital sound box unit terminal 13, a digital sound box unit signal processor 14, a power amplifier unit 15 and a speaker unit 16. As an option, a speaker parameter adjuster may be provided for a user to further regulate the box parameters.

Control and Process:

The signal from the analog audio source 3 is sent to the analog audio source input interface 4 of the decode and sound field acoustics effect process unit 20 of the present system. At first, the signal from analog audio source 3 is digitized, generally by A/D converter 5. The digital audio source I is directly coupled with an input interface of the digital audio source 2 of the decode and sound field acoustics effect process unit 20 according to the present system such that upon being selected from multiple inputs by gate circuit 6, the digital signals of audio source are digitally decoded and processed for digital sound field effect (may include many functional processes such as Dolby surround, Dolby digital (AC-3), DTS, DSP sound field, digital 3D sound field, digital Karaokey, digital equalize and etc.). Two or more channels of digital audio signals are output and divided into corresponding channels by the digital audio signal channel divider 8 in the control and encode unit 18. And then, beginning from the digital signal stream, signals from the volume and function controller 9 and other corresponding control signals (for example, the volume control signal, post-process control signal and mode selection control signal) are encoded, through the digital audio code and control code encoder 10, into a digital signal stream to form a standard encoded audio digital signal stream containing control information which is output from the digital transmission terminal 11.

The volume and function controller 9 can also be used to control the gate circuit 6, the effect processor 7 and other units (for example a display unit).

Transmission:

The transmission of the standard encoded audio digital signal stream of the present system takes the form of a variety of standard serial protocol, for example the standard S/PDIF protocol. The digital audio signal is carried in an audio data area of the S/PDIF whereas the audio data area is defined as single-channel mode (or only one of the double-channel used). The volume and control codes, encoded digitally, are loaded in a user code area (Ubit). The volume and control codes encoding is adopted as a reliable (with check and correction) and connectionless (real time) method.

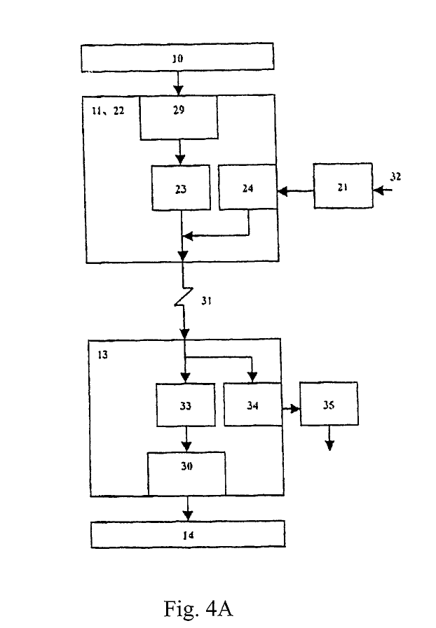

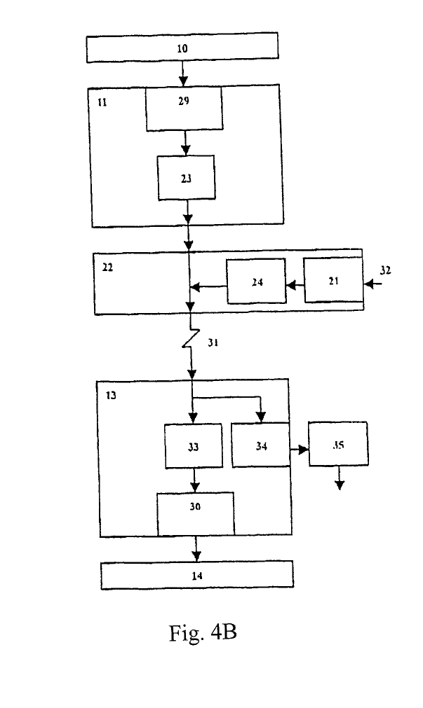

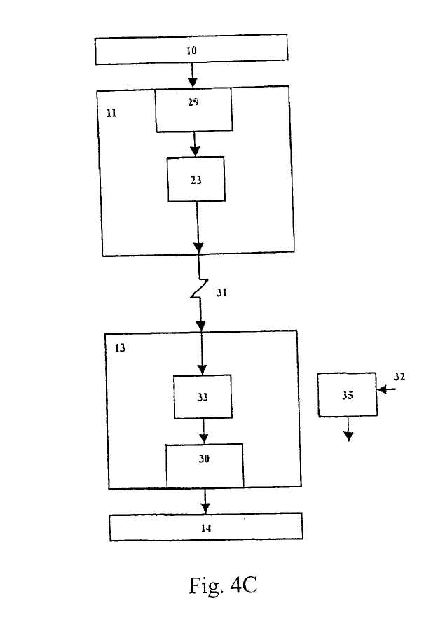

The type of the transmission medium at physical level 31 (see FIGS. 4A-4C) is selected mainly according to the principle of high rate and long distance, wherein the data rate must be more than 96K/32 Bit and the distance to be transmitted is over 15 meters. Thus, for example, optical fiber, coaxial cable or twisted pair line may be used.

If any of the structures shown in FIGS. 4A, 4B, 4C are adopted, it is suggested that a pair of twisted wires be used as the transmission medium. The standard encoded audio digital signal stream is then modulated by a digital signal modulator 29, and is mixed with the power supply 21 from mains 32 by a digital audio signal mixer via a power distributor 22 and a power mixing network 24 prior to being transmitted by a pair of wires. On the digital sound box unit port 13 the modulated standard encoded audio digital signal stream is separated from the power by means of the digital audio signal separation network 33 and the power separation network 34, whereby the power is fed into a sound box power supply 35 while the modulated standard encoded audio digital signal stream is fed into the digital sound box signal processor 14 after being demodulated by a digital audio signal demodulator 30.

If the structure shown in the FIG. 4C is adopted, power for the sound box can be supplied directly from mains 32 through a sound box power supply 35.

After being fed into the circuit of the digital sound box terminal 13, the standard encoded audio digital signal is processed, including digital frequency division, digital phase-frequency correction, digital amplitude-frequency correction, digital volume control and digital peak value correction by the digital sound box signal processor 14, divided into two or more channels of digital audio signals with different response spectrum and sent to a power amplifier 15 to drive the speaker unit 16 finally. The digital sound box unit 19 also feeds related condition signals back to control and encode unit 18 via the digital sound box terminal 13 and digital transmission terminal 11.

The sound box 17 and digital speaker 19 are designed according to mechatronics conception and adopt predictive compensation, which further optimizes the design of the sound box unit, and allows following design ideas to be realized more easily.

Digital Frequency Division:

The object of digital division is to divide the whole spectrum of an audio signal into two (or three or more) digital audio channel signals of low, mid in some case and high frequency ranges so as to drive bass, flat in some case, and treble speaker units, respectively, after being processed. The lowpass, bandpass in some case and highpass used by the present system are implemented with digital filters of appropriate orders and appropriate types. Digital division allows for the improvement of the electrical damping performance of the power amplifier towards the speaker unit, to use a more accurate and higher orders of frequency division resulting in a less band overlapping between both speaker units, and a reduced phase distortion.

Digital Phase-Frequency Correction:

The aim of the digital phase-frequency correction is to correct phase-frequency distortion at all links of the system, especially the phase-frequency distortion caused by the difference between the sounding plane of speaker units, to make the systematical “group delay” through the active spectrum of the sound boxes constant (linear phase-frequency).

Digital Amplitude-Frequency Correction:

The object of the digital amplitude-frequency correction is to correct the amplitude-frequency distortion resulting from such links, such as the sensitivity of the speaker units, sound box 17 and etc., to make the amplitude-frequency characteristics through the active spectrum of the sound boxes flat.

Digital Volume Control:

The function of the digital volume control is to receive volume control signals from the control and encode unit 18, and modulate the digital audio signal in order to control volume. Furthermore, the maximum volume of the loudspeaker unit 16 is necessary and can be limited to prevent the speaker from being burnt down because that the sensitivity of the loudspeaker unit 16, the power applied to the speaker unit 16 and amplification factor of the system are given (due to mechatronic design).

Digital Peak Correction:

Because both the voltage applied to the amplifier 15 and the peak power bearable by the speaker unit 16 are limited, an excessive peak power output causes serious chopping distortion, which can be corrected in the present system. The desired correction is possible by predicting following signal amplitude and adopting a method of gradual changing curve (soft saturation). After being corrected, the system performance and acoustics would be improved dramatically, resulting in smooth and graceful melodies.

The above-mentioned processes are based on the design concept of mechatronics and are determined by the characteristics of speaker unit 16 and sound box 17, tested during design and manufacture. In general, a top level of hi-fi is achieved by making sure that the distortions through all links of the system (especially the sound box 17 and the speaker unit 16) are compensated in a predictive way.

By the way, manufacturers and designers of sound boxes can accommodate timbre inclination of sound boxes, dynamic tendencies and local style inclination, according to their own ideas of design, so that products of unique brand style can be formed.

Further, users can enjoy their acoustics favorites by adjusting the setting of sound field or equalizer of the effect processor 7 of the present system.

Senior audio fans can even adjust the parameters of cut-off frequency, amplitude-frequency correction, phase-frequency correction and peak correction of the digital sound box unit signal processor 14 of the system through speaker parameter adjuster 12, to satisfy the individual taste of his own, or exchange experiences with other fans, or even take part in competitions.

Since the standard encoded audio digital signal stream is adopted in the data transmission of the present system, the independence from each other between the control & encode unit 18 and the digital speaker system 19 is ensured. In addition, because the digital sound box unit system is designed an manufactured under an integrated and high fidelity required architecture, independently from system specialties, the interdependency among various parts is reduced, allowing independent design and manufacture of separate various parts.

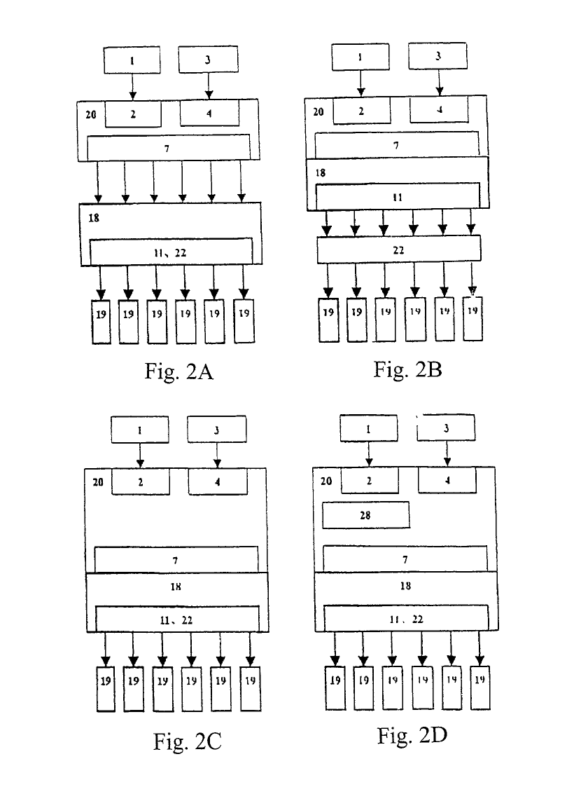

Referring to FIGS. 2A to 2D, control and encode unit 18, in the structure shown in FIG. 2A, is an independent device characterized in that the structure is clear but there are many connecting lines. Additionally, there are no available products of the decode and sound field acoustics effect process unit 20 which are suitable to be arranged in the present system. Control and encode unit 18 and the decode and sound field effect process unit 20 shown in FIG. 2B are in a combined structure, but the power distributor 22 is independent, thus allowing that the power supply can be selected freely. As shown in FIG. 2C a power distributor 22 is combined into the structure, making it easy to be installed. As shown in FIG. 2D, a CD, DVD driver 28, and the basic AV functions are combined together to form an AV audio system without additional devices. The structures shown in FIGS. 2C and 2D are more practical.

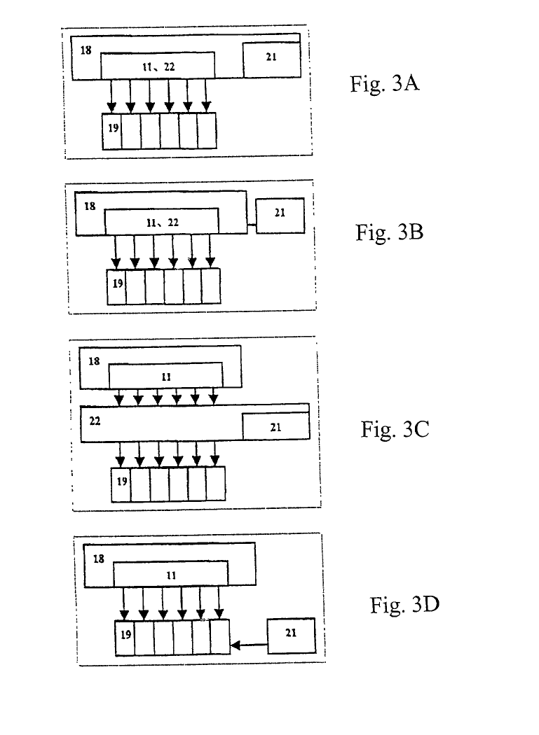

Referring to FIGS. 3A to 3D, the power supply 21 in FIG. 3A is disposed within the device. The power supply 21 in FIG. 3B is disposed outside of the device, connected through an interface. The power supply 21 in FIG. 3C is combined with the power distributor 22 and separated from the device. In FIG. 3D the power is directly supplied to the digital sound box unit 19. Each of the structures shown in FIGS. 3A to 3C has its own advantages. But it is more difficult to connect lines for the structure shown in FIG. 3D.

Referring to FIGS. 4A to 4C, FIG. 4A corresponds to FIGS. 3A and 3B. The digital audio signal separation network 33 allows modulated digital signal to be passed, but inhibits a power signal of low frequency, while the power separation network 34 allows power signal of DC or AC (50 Hz˜60 Hz) to be passed but inhibits high frequency digital signal. FIG. 4B corresponds to FIG. 3C while FIG. 4C corresponds to FIG. 3D where the power 35 is arranged according to the sound box itself.

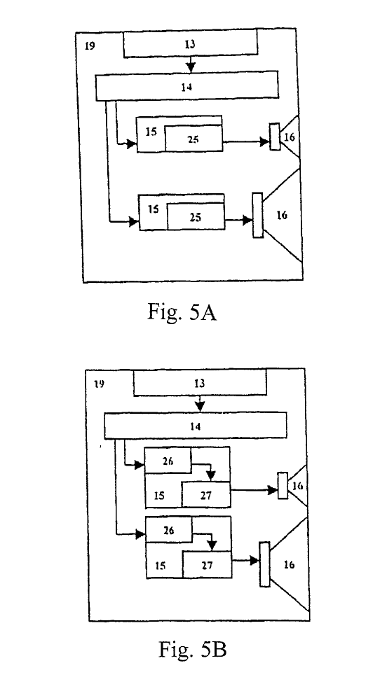

Referring to FIG. 5, the amplifier 15 shown in FIG. 5A is a sounding structure in which a digital power amplifier 25 (such as a class D amplifier) is adopted to drive loudspeaker units 16 directly. The amplifier 15 shown in FIG. 5B is a sounding structure in which the speaker unit 16 is driven through digital/analog converter 26 prior to an analog power amplifier 27.

1. A digital audio system comprising a power supply and a decode and sound field effect process unit, wherein digital audio signals output from the decode and sound field effect process unit are transmitted to a control and encode unit where audio and control signals are encoded and coupled with a digital sound box unit via a digital transmission terminal in the control and encode unit.

2. A system according to claim 1, wherein control and encode unit comprises a digital audio signal channel divider, a volume and function controller, a digital audio code and control code encoder and a digital transmission terminal, whereby after the digital audio signals from the decode and sound field effect process unit are processed by the digital audio signal channel divider, the control signal of the volume and function controller and other corresponding control signals are encoded into a digital audio signal by the digital audio code and control code encoder, to form a standard encoded audio digital signal stream containing control information, which is output from digital transmission terminal.

3. A system according to claim 1, wherein the digital sound box unit comprises a digital sound box unit terminal, a digital sound box unit signal processor, a power amplifier, a speaker unit and a sound box, whereby the standard encoded audio digital signal stream output from the digital transmission terminal are fed to the digital sound box unit terminal, subjected to digital division, digital phase-frequency correction, digital amplitude-frequency correction, digital volume control and digital peak value correction through the digital sound box unit signal processor, and then divided into two or more channels of digital audio signals to be fed into amplifier (15) to drive the speaker unit (16).

4. A system according to claim 3, wherein, a condition signal related to the digital sound box unit is fed back to the control and encode unit (18) from the digital sound box unit (19) via the digital sound box unit terminal (13) and the digital transmission terminal (11).

5. A system according to claim 1, wherein the signal processor, the speaker unit and the sound box of the digital sound box unit take a mechatronic configuration.

6. A system according to claim 2, wherein the signal processor, the speaker unit and the sound box of the digital sound box unit take a mechatronic configuration.

7. A system according to claim 1, wherein the decode and sound field effect process unit comprises a digital audio source, a digital audio source input interface, an analog audio signal source, an analog audio source input interface, an AID converter, a gate circuit and an effect processor which outputs two or more channels of digital audio signals to the control and encode unit.

8. A system according to claim 2, wherein the decode and sound field effect process unit comprises a digital audio source, a digital audio source input interface, an analog audio signal source, an analog audio source input interface, an AID converter, a gate circuit and an effect processor which outputs two or more channels of digital audio signals to the control and encode unit.

9. A system according to claim 7, wherein the volume and function controller controls the gate circuit and the effect processor.

10. A system according to claim 8, wherein the volume and function controller controls the gate circuit and the effect processor.

11. A system according to claim 1, wherein the parameters of cut-off frequency, amplitude-frequency correction, phase-frequency correction and peak value correction of the digital sound box unit signal processor in the digital sound box unit can be adjusted by a speaker parameter adjuster.

12. A system according to claim 4, wherein the parameters of cut-off frequency, amplitude-frequency correction, phase-frequency correction and peak value correction of the digital sound box unit signal processor in the digital sound box unit can be adjusted by a speaker parameter adjuster.

13. A system according to claim 5, wherein the parameters of cut-off frequency, amplitude-frequency correction, phase-frequency correction and peak value correction of the digital sound box unit signal processor in the digital sound box unit can be adjusted by a speaker parameter adjuster.

14. A system according to claim 6, wherein the parameters of cut-off frequency, amplitude-frequency correction, phase-frequency correction and peak value correction of the digital sound box unit signal processor in the digital sound box unit can be adjusted by a speaker parameter adjuster.
